(19) United States
(12) Patent Application Publication
(10) Pub. No.: US 2014/0256082 A1
(43) Pub. Date: Sep. 11, 2014

(54) METHOD AND APPARATUS FOR THE FORMATION OF COPPER-INDIUMGALLIUM SELENIDE THIN FILMS USING THREE DIMENSIONAL SELECTIVE RF AND MICROWAVE RAPID THERMAL PROCESSING

(71) Applicant: Jehad A. Abushama, San Jose, CA (US)

(72) Inventor: Jehad A. Abushama, San Jose, CA (US)

(21) Appl. No.: 14/177,238

(22) Filed: Feb. 11, 2014

Related U.S. Application Data
(60) Provisional application No. 61/773,984, filed on Mar. 7, 2013.

(51) Int. Cl. H01L 31/18

(52) U.S. Cl. CPC H01L 31/1864
USPC 438/95; 118/725

(57) ABSTRACT

A method of depositing CIGS thin films for solar panel construction comprising: providing a chamber; providing a substrate and placing said substrate inside said chamber; providing a material source; placing said material source inside said chamber; reducing pressure within said chamber; heating said substrate and said material source using electromagnetic heating (RF and Microwaves) source; perform deposition of said material source oto said substrate.

### INCORPORATION BY REFERENCE

This application claims the benefit of priority under 35 U.S.C. 119(e) to the filing date of U.S. provisional patent application No. 61/773,984 titled “METHOD AND APPARATUS FOR THE FORMATION OF COPPER-INDIUM-GALLIUM-SELENIDE THIN FILMS USING THREE DIMENSIONAL SELECTIVE RF AND MICROWAVE RAPID THERMAL PROCESSING” which was filed on Mar. 7, 2013, and which is incorporated herein by reference in its entirety.

### FIELD OF THE INVENTION

The present invention relates to a thin film solar cell, and more particularly to a method and apparatus for the manufacturing a Copper-Indium-Gallium-Selenide (CIGS) thin films using three dimensional (3-D) selective Radio Frequency (RF) and microwave rapid thermal processing.

### BACKGROUND OF THE INVENTION

The present invention relates generally to photovoltaic techniques. More particularly, the present invention provides a method and structure for a thin-film photovoltaic device using Copper-Indium-Gallium-Selenide, and other materials. In general, solar cells are photovoltaic devices that convert sunlight directly into electrical power. The most common solar cell material is Silicon (Si), which is in the form of single or polycrystalline wafers. However, because the cost of electricity generated using silicon-based solar cells is higher than the cost of electricity generated by the more traditional methods, a method to reduce the cost of solar cells is desirable. One way of reducing the cost of solar cells is to develop low-cost thin film growth techniques that can deposit solar-cell-quality absorber materials on large area substrates and to fabricate these devices using high-throughput, low-cost methods. A thin-film solar cell (TFSC), which is also known as thin film photovoltaic cell (TFPVC), is a solar cell that is made by depositing one or more thin layers of photovoltaic materials on a substrate.

In general, solar cells are classified into various types according to a material of the light-absorbing layer. Solar cells may be categorized into silicon solar cells having silicon as a light-absorbing layer, compound thin film solar cells using CIS (CuInSe2) or CdTe, III-V group solar cells, dye-sensitized solar cells, and organic solar cells.

Among the solar cells, silicon solar cells include crystalline solar cells and amorphous thin film solar cells. While bulk-type crystalline solar cells are widely used, the crystalline solar cells have high production cost due to expensive silicon substances and complicated manufacturing processes. However, by forming a solar cell of a thin film type on a relatively low cost substrate, such as glass, metal, or plastic, instead of a silicon wafer, reduction of photovoltaic production cost can be achieved.

Different photovoltaic materials are available to be deposited with various deposition methods on a variety of substrates, and the resultant thin-film solar cells are usually categorized according to the photovoltaic material used. Group IBIIIAVIA compound semiconductors comprising some of the Group IB (Cu, Ag, Au), Group IIIA (B, Al, Ga, In, Tl) and Group VIA (O, S, Se, Te, Po) materials or elements of the periodic table are excellent absorber materials for thin film solar cell structures. Generally, photovoltaic compounds that include amorphous silicon (a-Si), Cadmium telluride (CdTe), and Copper-Indium-Gallium-Selenide (CIS or CIGS) are referred to as thin film solar cells.

Polycrystalline Copper Indium Gallium Diselenide or Cu(In,Ga)Se2 (CIGS) is the most promising of all thin film solar cells. Recently, the record efficiency of laboratory size CIGS thin film solar cells reached 20.8%. A typical device structure for a CIGS solar cell is illustrated in FIG. 1.

In this review and throughout the present invention disclosure, the different pieces of the solar cell will be referred to as shown in FIG. 1. In other words, 100 refers to the substrate, which can be made of Glass (e.g. Soda-Lime-Glass (SLG) or flexible glass), Metallic sheets or Plastic sheets (e.g. Polyimide); 101 refers to the barrier layer (e.g. SiO2 or SiN), 102 refers to the back contact layer which can be made of one or more refractory metals like Molybdenum (Mo), Niobium (Nb), Tantalum (Ta), Tungsten (W) and/or Rhenium (Re); 103 refers to the CuInGaSe2 (CIGS) absorber layer; 104 refers to the buffer layer which can be made of CdS, ZnS, ZnO, In2Se3, and/or In2S3; 105 refers to an intrinsic layer (e.g. i-ZnO) followed by a transparent conduction oxide-TCO layer (e.g. Indium-Tin-Oxide (ITO) or Al:ZnO); and 106 refers to the metallic grids and Anti-reflecting (AR) coating.

Typically, a CIGS thin film may be deposited on a number of substrates S 100 including glass (whether rigid or flexible), metallic sheets or plastic sheets (e.g. polyimide). A barrier layer L1 101 may be deposited on the substrate to minimize and/or prevent the diffusion of impurities from the substrate to the CIGS thin film. A back-contact layer L2 102 (e.g. Molybdenum-Mo or another refractory metal layer of about 1 μm thickness) may be deposited on the barrier-layer coated substrate using DC magnetron sputtering. On top of the back-contact layer 102, a CIGS layer L3 103 is deposited. For making solar cells, a CIGS chalcopyrite structure is required. Co-evaporation yielded the best device conversion efficiency of 20.8%. A typical high efficiency CIGS device has a Cu(In+Ga) ratio of 0.80-1.0 and a Ga(In+Ga) ratio of ˜0.30. This Ga/(In+Ga) ratio can be varied from 0-1. The formation of CIGS thin film requires high temperature (450-800° C.). To complete the solar cell structure, a thin buffer layer L4 104 of about 500-1200 Å thickness (e.g. Cadmium Sulfide-CdS) is deposited on top of the CIGS layer, followed by depositing an intrinsic layer followed by depositing a transparent conducting oxide-TCO (e.g. i-ZnO/Al—ZnO or i-ZnO/ITO) L5 105; followed by depositing metallic front contacts and anti-reflecting coating (AR) L6 106. The best known method for depositing CdS, TCO and front contacts are Chemical Bath Deposition (CBD), RF sputtering and evaporation, respectively.

A temperature in the range of (450-800° C.) is usually required to make Cu-poor CIGS chalcopyrite structures from which CIGS thin film solar cells can be made. This temperature range is usually achieved by traditional heating methods (e.g. Infrared heating or Resistive/Electrical heating).

Currently in the existing art, there are two approaches to activate the formation of the CIGS chalcopyrite structure:

Approach I:

In this approach, all four elements (Cu, In, Ga and Se) are deposited by Physical Vapor Deposition-PVD) or another method onto an IR-heated substrate 100 which is already coated with a barrier layer 101 and/or back contact layer 102. As shown in FIG. 1, the substrate 100 can be Soda-Lime-Glass, other types of glass, a Metallic sheet or a Plastic sheet such as Polyimide. An appropriate heat profile such as the well-known three-stage process can be used.

In the first stage of the three-stage process, In and Ga are evaporated in the presence of Se vapor onto a heated substrate (at about 400° C.). In the second stage of the three-stage process, Cu is evaporated in the presence of Se vapor onto the heated substrate (at about 600° C.). In this stage, Cu-rich CIGS phase is formed. In the third stage, small amounts of In and Ga are evaporated to convert the CIGS structure into the Cu-poor Chalcopyrite CIGS phase from which CIGS thin film solar cells can be made. All stages are usually implemented under high vacuum (preferably a pressure of less than 1×10⁻⁶ Torr). Typically, depositing a CIGS film using the three stage process takes about 40 minutes. Usually, Sodium which is an important dopant for CIGS crystallization is introduced through the Soda-Lime-Glass (which has Na as part of its constituents) or from an external source to have a better control on the amount introduced or if a different substrate is used.

Approach II:

In this approach, Cu, In and Ga are deposited onto an unheated substrate 100 which is already coated with a barrier layer 101 and/or a back contact layer 102 as depicted in FIG. 1. Sodium (Na) which is an important dopant for CIGS crystallization is introduced through the Soda-Lime-Glass or from an external source to a have better control on the amount introduced or if a different substrate is used.

The (Cu,In,Ga) layer deposited on 102/101/100 structure is then placed inside a furnace that's capable of going up to the CIGS crystallization temperature of (400-800° C.). The structure is then heated up to >400° C. in the presence of Se. This selenization and heating steps are necessary to activate the formation of the CIGS chalcopyrite structure.

In both approaches above, traditional heating methods (Infra-Red-IR heating or resistive/electrical heating) are usually used as the methods for heating the substrate and activating the formation of CIGS.

Typically, Approach I results in more uniform compositional uniformity compared with Approach II which results in the well-known Ga-segregation problem in the back of the thin film and lateral compositional non-uniformity. Since In and Ga compete for Se, along with Cu, the composition of all elements is non-uniform and this causes losses in solar cell performance.

Lateral compositional non-uniformity and Ga segregation in the back of the film are more dominant in Approach II described above for the formation of the CIGS chalcopyrite structure from which thin film CIGS solar cells are made. In both approaches described above for activating the CIGS formation, Ga has the least compositional uniformity, laterally and along the depth of the film. This is because of Ga physical properties. Because of Ga segregation problem, Sulfur can be used to increase the bandgap near the surface of Cu(In,Ga)(S,Se)2.

In the process of manufacturing CIGS thin films, there are various manufacturing challenges such as maintaining the structural integrity of substrate materials, ensuring uniformity and granularity of the thin film material, minimizing materials loss during the deposition process, etc. Conventional techniques that have been used so far are often inadequate in various situations and are so far incapable of producing cost-effective solar panels. Therefore, it is desirable to have improved systems and methods for manufacturing CIGS thin film photovoltaic devices.

### OBJECT OF THE INVENTION

Accordingly, one objective of this invention is to provide a superior three-dimensional heating method.

Another objective of this invention is to provide a simple and low cost manufacturing method of solar cells.

Yet another objective of this invention is to provide a method to manufacture solar cells using low cost substrates.

Yet another objective of this invention is to provide an improved method to manufacture solar cells using Cu, In, Ga, and Se.

Yet another objective of this invention is to eliminate Ga segregation problem in a solar cell's absorber layer resulting from certain deposition processes.

Yet another objective of this invention is to use electromagnetic heating method to produce three-dimensional heating.

Yet another objective of this invention is to produce a uniform solar cell composition.

Yet another objective of this invention is to use Radio-Frequency (RF) waves as a heating method to activate the formation of the solar cell absorber layer.

Yet another objective of this invention is to use microwaves as a heating method to activate the formation of the solar cell absorber layer.

Yet another objective of this invention is to use a susceptor capable of being heated by absorbing electromagnetic waves (RF and Microwaves).

Yet another objective of this invention is to use a material structure that's capable of being transparent to electromagnetic waves (RF and Microwaves).

Another objective of this invention is to use electromagnetic heating (RF and Microwaves) to heat a chemical medium and activate the formation of a buffer layer in a solar cell.

Another objective of this invention is to form the solar cell buffer layer comprised of CdS using electromagnetic heating (RF and Microwave) as the heating method

Another objective of this invention is to form the buffer layer comprised of ZnS using electromagnetic heating (RF and Microwaves) as the heating method.

Another objective of this invention is to form the buffer layer comprised of In2Se3 and/or In2S3 using electromagnetic heating (RF and Microwaves) as the heating method.

Another objective of this invention is to heat the chemical medium to temperatures less than 100° C. (typically ˜70° C.) using electromagnetic (RF and Microwaves) heating as the heating method.

Another objective of this invention is to selectively heat certain layers in a multi-layer solar cell structure using electromagnetic (RF and Microwaves) heating.

Another objective of this invention is to remotely use contactless electromagnetic (RF and Microwaves) heating as the heating method to heat: (1) the source materials (e.g. Cu, In, Ga, Se, CuIn, CuGa, CuInGa and/or all other combinations) required to deposit the CIGS absorber layer in a CIGS solar cell; (2) the substrate structure on which the CIGS layer is deposited; (3) other layers in the CIGS solar; and (4) the chemical solution required to prepare the buffer layer (by Chemical Bath Deposition-CBD) in a CIGS solar cell.

### SUMMARY OF THE INVENTION

In one aspect of the invention, a method for depositing CIGS thin films for solar panel construction is disclosed. The method comprises providing a chamber, providing a substrate and placing said substrate inside said chamber, providing a metallic source, placing said metallic source inside said chamber, reducing pressure within said chamber, heating said substrate with an electromagnetic heating source, and perform a deposition of the metals in said metallic source to said substrate. In one embodiment, the pressure within the chamber is less than 1×10⁻⁶ Torr. In another embodiment, the electromagnetic heating source is comprised of radio frequency waves. In yet another embodiment, the electromagnetic heating source is comprised of microwaves. In yet another embodiment, the aforesaid method comprises placing said substrate within a first susceptor. In yet another embodiment, the first susceptor is made of material capable of absorbing electromagnetic waves (RF and Microwaves) from said electromagnetic heating source. In yet another embodiment, the first susceptor is made of material transparent to electromagnetic waves (RF and Microwaves) from said electromagnetic heating source. In yet another embodiment, the first susceptor is coated with material capable of absorbing electromagnetic waves (RF and Microwaves) from the aforementioned electromagnetic heating source. In yet another embodiment, the aforesaid method further comprises placing the metals of the metallic source in an open boat or crucible. In yet another embodiment, the method further comprises placing the open boat or crucible on a second susceptor wherein a second electromagnetic heating (RF and Microwaves) source is provided. In yet another embodiment, the second susceptor is made with material capable of absorbing electromagnetic waves (RF and Microwaves) from the second electromagnetic heating source. In yet another embodiment, the first susceptor is coated with material capable of absorbing electromagnetic waves (RF and Microwaves) from the electromagnetic heating source. In yet another embodiment, the open boat or crucible is coated with material capable of absorbing electromagnetic waves (RF and Microwaves) from said second electromagnetic heating source. In yet another embodiment, the open boat or crucible is heated with said second electromagnetic heating source. In yet another embodiment, the substrate comprises multiple layers. In yet another embodiment, at least one of the multiple layers is made with material capable of absorbing electromagnetic waves (RF and Microwaves) from said electromagnetic heating source. In yet another embodiment, the material capable of absorbing RF and microwaves is comprised of SiC. In yet another embodiment, the multiple layers include a barrier layer and a back contact layer. In yet another embodiment, the substrate is positioned to the electromagnetic heating source at an optimal distance and to the metallic source at a distance from 1 mm to 30 cm. In yet another embodiment, the metallic source is made with elements selected from the group consisting of Cu, In, Ga, CuIn, CuGa, CuInGa and/or other combinations. In another embodiment, a Se source is placed inside the chamber. In yet another embodiment, select combination of Cu, In, Ga, CuIn, CuGa or CuInGa and Se are deposited on the substrate simultaneously so that the Cu/(In+Ga) ratio ranges from 0.7-0.9 and the Ga/(In+Ga) ratio ranges from 0-1. In yet another embodiment, select combination of Cu, In, Ga, CuIn, CuGa or CuInGa and Se are deposited on the substrate separately so that the Cu/(In+Ga) ratio ranges from 0.7-0.9 and the Ga/(In+Ga) ratio ranges from 0-1. In yet another embodiment, the electromagnetic heating source heats the substrate at a temperature ranging between 300-800° C. In yet another embodiment, the electromagnetic heating source is comprised of fixed or variable frequency electromagnetic waves (RF and Microwaves).

In one aspect of the invention, a method of depositing CIGS thin films for solar panel construction is disclosed, comprising providing a chamber, providing a substrate and placing it inside the chamber wherein the substrate is already coated with Cu, In and Ga by physical vapor deposition, providing a Se source, placing the Se source inside the chamber, reducing the pressure in the chamber, heating the substrate with an electromagnetic heating source, and selenizing the Cu, In, Ga and/or its alloys on the substrate.

In one embodiment, Sodium is used as dopant for CIGS absorber layer. In another embodiment, the Se source is in a gaseous state and is introduced to said substrate via tubing. In another embodiment, the tubing is further comprised of a valve that controls the flow of the gaseous Se source. In yet another embodiment, N2 or Ar gas is introduced via the tubing. In yet another embodiment, the electromagnetic heating source is comprised of variable frequency electromagnetic waves (RF and Microwaves).

In one aspect of the present invention, a method for depositing CIGS thin films for solar panel construction is disclosed, comprising providing a first chamber comprised of a first enclosure, and a second enclosure, wherein said first enclosure is comprised of a heating vessel enclosing a metallic source providing the Cu, In, and Ga in the form of CuInGa alloy powder; said heating vessel is made of a material capable of absorbing RF and Microwaves and capable of being heated using electrical resistive heating (e.g. SiC); said heating vessel can be heated using a heating source; said second enclosure is comprised of a reaction box which encloses the substrate already coated with the barrier layer and/or back contact layer; said reaction box is made of material capable of absorbing RF and Microwaves. Said CIG powder is heated by a first heating source, converting the CIG powder into CIG vapor. Said CIG vapor is transported by a carrier gas (e.g. N2) delivered from a carrier gas source outside said chamber and tubing connecting the heating vessel with the reaction box for such delivery. Said heating vessel is heated to a temperature capable of changing the CIG powder into CIG vapor using electromagnetic (RF and Microwave) heating or electrical resistive heating. Said reaction box is heated to a 400-800° C. temperature which is capable of forming the CIGS chalcopyrite phase using electromagnetic (RF and Microwave) heating. Said CIG vapor is transported to the substrate using the tubing and the carrier gas. Se vapor with the carrier gas or H2Se gas is delivered from a second chamber to the substrate in the reaction box using second tubing at the same time as the CIG vapor is delivered to said substrate using first tubing. Said vaporization of CIG powder in the said heating vessel and said reaction between H2Se gas or Se vapor and CIG vapor is implemented under reduced pressure of said chamber.

In one embodiment, the Cu, In and Ga is in CuInGa alloy powder form before they are heated by the first heating source. In another embodiment, the first heating source is an electrical heating source. In yet another embodiment, the first heating source is a second electromagnetic heating source comprised of RF and Microwaves. In yet another embodiment, the second electromagnetic heating source originates from the first electromagnetic heating source. In yet another embodiment, the electromagnetic heating source is variable frequency electromagnetic heating.

In one aspect of the present invention, an apparatus for deposition of a plurality of elements onto a solar cell substrate is disclosed, comprising a chamber, a substrate, a plurality of elements for deposition onto the substrate, an electrical source to conduct the deposition, an electromagnetic heating source to heat the substrate, and a vacuum source to control the pressure environment of the chamber.

In one embodiment, the substrate is positioned at an optimal distance from the electromagnetic heating source and at a distance of from 1 mm to 30 cm from the source material. In another embodiment, the electromagnetic heating source heats the substrate to a temperature ranging between 300-800° C. In yet another embodiment, the substrate is positioned within a susceptor, which is made with material capable of absorbing electromagnetic waves (RF and Microwaves) from said electromagnetic heating source. In yet another embodiment, the susceptor is made with material transparent to electromagnetic waves (RF and Microwaves) from the electromagnetic heating source. In yet another embodiment, the plurality of elements for deposition onto the substrate is placed in an open boat or a crucible. In yet another embodiment, a second electromagnetic heating source is provided to heat a susceptor upon which the open boat or crucible is placed. In yet another embodiment, the susceptor is made of material capable of absorbing electromagnetic waves (RF and Microwaves) from the second electromagnetic heating source. In yet another embodiment, the crucible or open boat is coated with material capable of absorbing electromagnetic waves (RF and Microwaves) from the second electromagnetic heating source. In yet another embodiment, the plurality of elements for deposition onto the substrate is transported into a first enclosure via tubing and a carrier gas. Said first enclosure is comprised of a reaction box and placed inside the chamber. In yet another embodiment, the electromagnetic heating source is fixed frequency electromagnetic heating.

In one aspect of the present invention, an apparatus for deposition of a plurality of elements onto a solar cell substrate is disclosed, comprising a chamber, a substrate, a plurality of elements for crystallization onto the substrate, an electromagnetic heating source to heat the substrate and to conduct crystallization of the plurality of elements to the substrate, a vacuum source to control the pressure of the chamber.

In one embodiment, the plurality of elements for crystallization onto the substrate is carried into said reaction box inside the chamber via tubing and a carrier gas. In yet another embodiment, the apparatus further comprises a second enclosure within the chamber that comprises a heating source to heat the said second enclosure, and changes a first portion of the plurality of elements to gaseous state, which is thereby transported to the substrate for crystallization via tubing and a carrier gas. Said first portion of plurality of elements is comprised of CuInGa powder alloy. In yet another embodiment, the plurality of elements is transported to the substrate for crystallization via first tubing and a carrier gas. In yet another embodiment, the second portion of the plurality of elements is transported to the substrate for crystallization via second tubing. Said second portion of the plurality of elements is comprised of Se vapor and/or H2Se gas. In yet another embodiment, heating source is a second electromagnetic heating source comprised of RF and Microwaves. In yet another embodiment, the tubing is coupled with a valve to control the transportation of the plurality of elements and carrier gases. In yet another embodiment, the electromagnetic heating source is variable frequency electromagnetic (RF and Microwaves) heating.

In another aspect of the invention, a method for depositing the buffer layer in a CIGS thin film solar cell for solar panel construction is disclosed comprising providing a vessel wherein the vessel further comprises a water-based solution wherein the water-based solution further comprises a chemical bath solution for depositing the buffer layer using Chemical Bath Deposition (CBD); providing a substrate and placing the substrate inside the vessel; providing an electromagnetic heating source comprised of RF and microwaves; heating the vessel and the water-based chemical bath solution using said electromagnetic heating source; allowing the buffer layer to deposit onto the substrate as the water-based chemical bath solution is heated. In one embodiment, the buffer layer is Cadmium Sulide. In one embodiment, the buffer layer is Zinc Sulfide (ZnS). In one embodiment, the buffer layer is Indium Sulfide (In2S3). In one embodiment, the buffer layer is Indium Selenide (In2Se3)

### BRIEF DESCRIPTION OF THE DRAWINGS

These and other features and advantages of the invention will not be described with reference to the drawings of certain preferred embodiments, which are intended to illustrate and not to limit the invention, and in which:

FIG. 1 is a schematic diagram illustrating a typical CIGS solar cell structure, including a CIGS thin film deposited on a number of substrates.

FIG. 2 is a schematic diagram illustrating a method and system using Electromagnetic Heating (EMH-RF and Microwaves) to prepare CIGS thin films from single elemental sources for Cu, In, Ga, and Se.

FIG. 3 is a schematic diagram illustrating a method and system using Electromagnetic Heating (EMH-RF and Microwaves) to prepare CIGS thin films from a single CuInGa (CIG) source (CIG in this case in powder) and a single Se source.

FIG. 4 is a schematic diagram illustrating a method and system using Electromagnetic Heating (EMH-RF and Microwaves) to prepare CIGS thin films from a single CuInGa (CIG) source and a single Se source.

FIG. 5 is a schematic diagram illustrating the deposition of Cu, In, Ga, or CIG powder by evaporation, and CIG or CuGa/In by sputtering.

FIG. 6 is a schematic diagram illustrating the selenization of the Cu, In, Ga, Se structure.

FIG. 7 is a schematic diagram illustrating the selenization of the Cu, In, and Ga structure.

FIG. 8 is a schematic diagram illustrating the selenization of the Cu, In, and Ga structure prepared from CIG powder.

FIG. 9 is a schematic chart illustrating the surface composition profiles of: (a) non-uniform in case of conventional heating; and (b) uniform in case of VFEMH (RF and microwaves).

FIG. 10 is a schematic chart illustrating the depth composition profiles of: (a) non-uniform in case of conventional heating; and (b) uniform in case of VFEMH (RF and microwaves).

FIG. 11 is a schematic diagram illustrating a Chemical Bath Deposition (CBD) for the preparation of CdS or ZnS using RF/Microwaves heating method.

### DETAIL DESCRIPTION OF THE INVENTION

This invention disclosed herein is a method for heating Cu, In, Ga and Se using Electromagnetic heating in the forms of RF and Microwaves (hereinafter as “EMH”) to form more uniform CIGS absorber layers.

EMH method has a number of advantages: EMH system can be designed in such away to selectively heat the sample but not the vessel in which the sample is placed as EMH is more of a remote method of heating as opposed to heating by conduction, convection and/or radiation. EMH takes advantage of the ability of some materials to convert RF and microwave electromagnetic waves into heat. There are two methods of EMH: (1) Fixed Frequency Electromagnetic (or microwave) Heating (FFEMH); and (2) Variable Frequency Electromagnetic (or microwave) Heating (VFEMH).

VFEMH results in more uniform heating compared with FFEMH. VFEMH systems are available for a number of industrial applications (e.g. adhesives cure, etc.).

EMH offers a rapid method for uniform heating compared with conventional methods. EMH causes the molecules in the material to oscillate generating heat. Since this EMH method is contactless and selective, it can be accurately designed to control heating with more uniformity. In conventional heating (convection, conduction or radiation), the surface of a sample is heated first, then, heat transfers by conduction to other parts of the sample. VFEMH furnaces result in more uniform heating compared with FFEMH and conventional heating methods. EMH is a three-dimensional (3-D) heating method that heats the overall volume of a material. In traditional heating methods, the surface is heated first, then, heat is transferred inward.

There are many references that talk about heating using RF and Microwaves. For example, U.S. Pat. No. 8,207,478 B2 by Tian et al. titled “METHOD AND APPARATUS FOR RAPID THERMAL PROCESSING AND BONDING OF MATERIALS USING RF AND MICROWAVES” talked about using variable frequency microwave heating to heat a number of materials.

The invention presented herein is to apply EMH (RF and Microwaves) to heat anneal Cu, In, Ga, Se and NaF to form a partially- or fully selenized and sodium-doped CuInGaSe2 thin film layers. FFEMH or VFEMH method may be used to rapidly anneal Cu, In, Ga, Se and NaF in order to form CuInGaSe2 thin films (<2 μm in thickness). VFEMH offers rapid and instant heating without ramping up or down in heat profiles.

Approaches I and II above describe the methods for reacting Cu,In,Ga, and Se and forming Cu-poor CIGS thin films from which thin film solar cells can be made.

This invention disclosure presents a new and novel combination of heating the different constituents in a Cu,In,Ga, and Se structure using EMH to form CIGS thin films. EMH can be applied using the following three methods:

### Method I

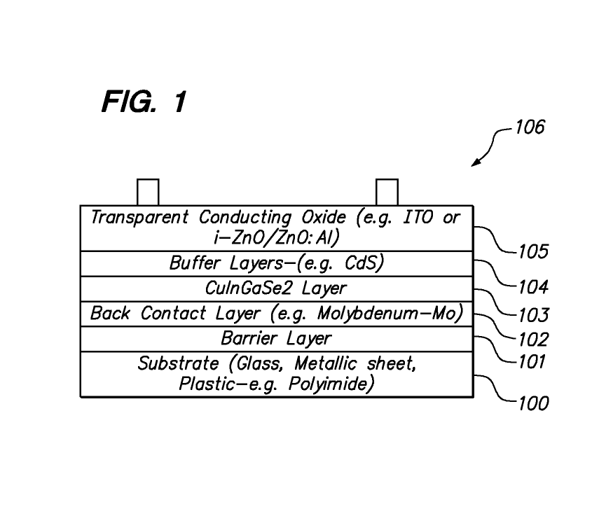

In this method (in reference to FIG. 1), all four elements (Cu, In, Ga and Se) are deposited (for example, by Physical Vapor Deposition-PVD) onto an EMH-heated substrate 100 already coated with a barrier layer-101 and/or back contact layer 102. The substrate 101 can be Glass (whether rigid or flexible), a Metallic sheet or a Plastic sheet such as Polyimide. NaF can be introduced from an external source or from SLG in case SLG is used as a substrate. This deposition process takes place under high vacuum (<1×10⁻⁶ Torr).

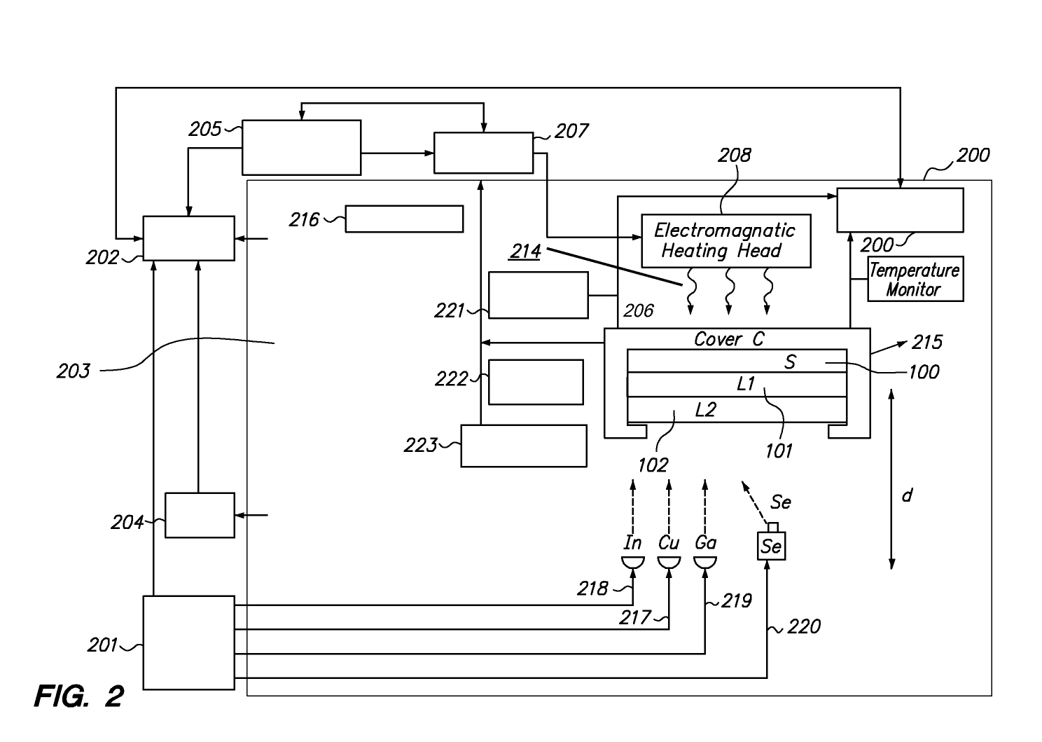

The following heat profiles can be used (in all of them, the deposition temperature is >400° C.):
1) A three step process where the different elements are deposited (using Evaporation) onto a substrate heated using EMH (RF and Microwaves). The deposition of Cu, In, Ga and Se is similar to Approach I above. The deposition time can range from 1-50 minutes.
2) A single stage co-evaporation or a co-sputtering process of all elements onto the EMH heated substrate. In this case, Cu, In, Ga and Se are delivered at the same time. Deposition times can range from 1-50 minutes.
3) A two stage process where Cu, In, Ga, and Se are evaporated onto an EMH heated substrate at a temperature ranging from 300-800° C. until the film is slightly Cu-rich followed by the deposition of In, Ga and Se to convert the structure to Cu-poor CIGS with 0.80-0.90 Cu/(In+Ga) ratio.
4) A two stage process where Cu, In, Ga, and Se are deposited onto an EMH-heated substrate at a temperature ranging from 300-800° C. In the first stage of this process, Cu/(In+Ga) ratio ranges from 0 to 0.80-0.90. In the 2nd stage, Cu is deposited in the presence of Se vapor at a temperature ranging from 400-800° C. until the film reaches a Cu/(In+Ga) ratio of 0.80-0.90.
5) All the above 1-4 procedures but with the addition of small amount of In to improve the surface properties (amount of In is <1000 Å).
6) All the above procedures can have a Ga/(In+Ga) ratio ranging from 0-1.
7) Referring to FIG. 2, in one embodiment, a bell jar system 200 is used and pumped down to less than 1×10⁻⁶ Torr pressure. The system comprises of an electrical power source 201 that powers the heating heads and a computer system 202. The system further comprises a processing chamber 203, a vacuum pump 204, a variable frequency EM power source 205, and a K-thermocouples 206, which are controlled by the computer system 202. The system further comprises a measurement control 207, which regulates the EM power source 205, and also provides feedback to it. The processing chamber 203 comprises an electromagnetic heating head 208. In addition, the system 200 is further comprised of temperature control module 221 which through temperature feedback 222 provides feedback to measurement controls 207. In another embodiment, the system 200 is further comprised of a thickness controller 223 that controls the thickness of the deposited In 218, Cu 217, Ga 219, and/or Se 220 onto the substrate 102/101/100 structure. The substrate 100 can be flexible or rigid glass (Soda lime or another type), metallic sheet or plastic sheet. The cover C 205 can be a susceptor which is capable of absorbing electromagnetic waves (RF and Microwaves) and converting them into heat. 101 is a barrier layer which is capable of preventing diffusion of impurities into the CIGS thin film. 102 is the back contact layer which can be any refractory metal (e.g., Molybdenum (Mo), Tungsten (W), Niobium (Nb), Tantalum (Ta), and/or Rhenium (Rh). NaF can be deposited as a separate layer on top or underneath the back contact layer 102.

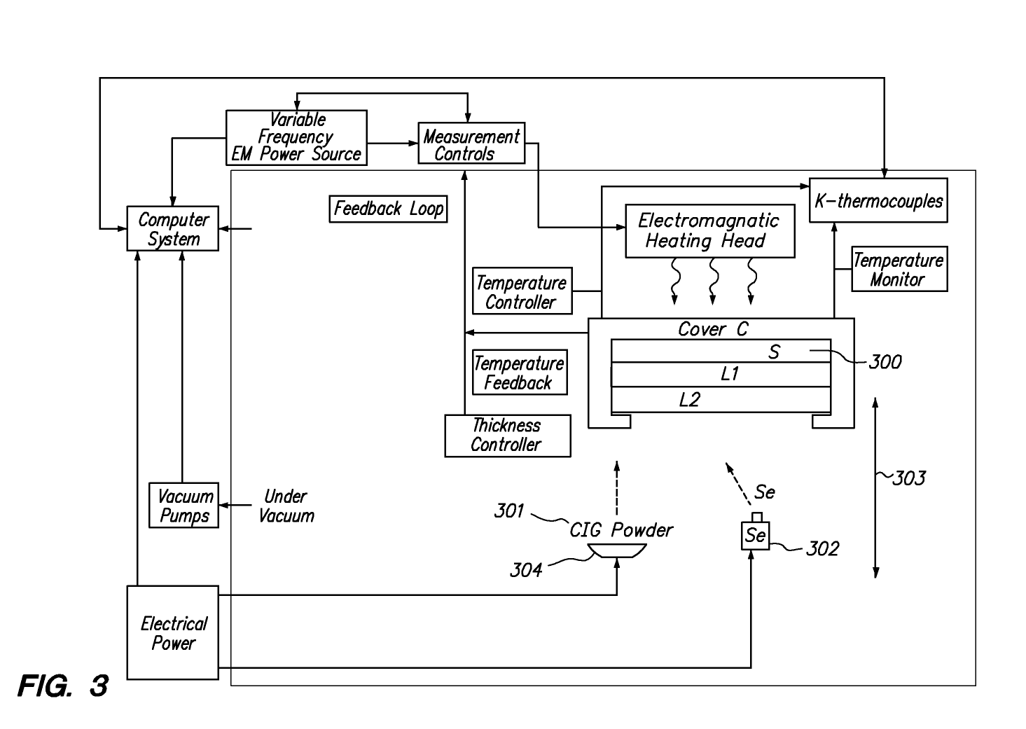

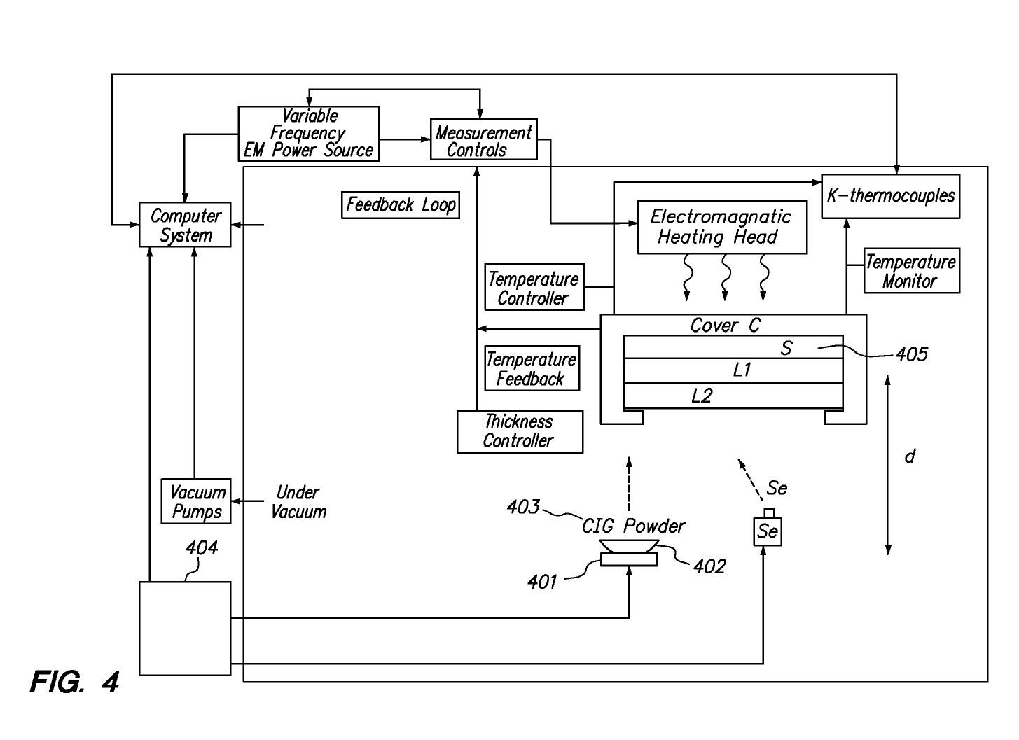

To start the deposition, the EM power source 201 is turned on. The EM waves 214 are then transferred to the heating head which will heat the susceptor C 215 using EMH (RF and Microwaves). Susceptor C 215 should be selected from a class of materials capable of absorbing EM waves (RF and Microwaves) and converting them into heat, e.g., Silicon Carbide (SiC), Silicon Nitride (SiN), Silicon Carbide Nitride (SiCN), etc. Heat will transfer by conduction to the substrate S 100, L1 101 and L2 102, respectively. The feedback loop 216 controls the substrate temperature to the desired one (>400° C.). For example, in the 3 stage process, the temperatures of stage 1, 2 and 3 are ˜400, 600 and 600° C., respectively. Once the substrate reaches the required temperature, Cu 217, In 218, Ga 219 and Se 220 are deposited by turning on the electrical power sources 201, and using one of the procedures 1-6 above. The thickness of the CIGS layer is less than 5 μm (typically, 1.5-2.0 μm), which can be achieved by depositing the appropriate Cu, In, Ga and Se thicknesses. This way the deposited film is ready and can be taken out and processed into a complete solar cell similar to the one shown in FIG. 1.
8) Still referring to FIG. 2, procedure 8 is similar to 7 above, except that the cover C 215 is transparent to EM waves (RF and Microwaves) and is not heated up as EM waves (RF and Microwaves) 214 pass through. The substrate (S) 100 can be made of glass or plastic. The barrier layer 101 is selected from a class of materials that absorbs EM waves (e.g. SiC). Glass substrate 100 and the barrier layer 101 are heated using EMH thereby causing the back contact layer 102 to be heated by conduction. Once the Mo or back contact layer 102 reaches the required temperature, deposition can start as stated in procedure 7 above.
9) In reference to FIG. 3, procedure 9 comprises all of the above, but replaces all three Cu, In and Ga sources with one source of CuInGa (CIG) alloy powder 301 (with Cu/(In+Ga) ranging from 0.80 to 0.90). In one embodiment, this procedure comprises using electrical heating to heat up both CIG 301 and Se 302 and make Cu-poor CIGS from which CIGS solar cells can be made. The substrate 300 is heated using EMH.
10) Continues to refer to FIG. 3, procedure 10 comprises all of the above where the distance “d” 303 from the CIG 301 and Se 302 material sources to the substrate structure 300 comprised of 102/101/100 ranges from 1 mm to 30 cm, and the four elements to be deposited are from different individual sources such as open boats 304, and/or crucibles 302. The substrate structure 300 is heated using EMH.
11) Referring to FIG. 4, procedure 11 comprises all of the above, but replaces the open boats and/or crucibles with ones that are coated with or made from materials that absorb EM waves (RF and Microwaves) 402 and convert them into heat. SiC (or another material that is capable of absorbing EM waves and converting them into heat) can be used for coating or fabricating the open boats or crucibles 402. In this procedure, a second electromagnetic heating source 404 replaces Electrical Heating source to heat up the coated boats or crucibles 402. The heat generated by second electromagnetic heating source 404 in these open boats or crucibles will transfer to Cu, In, Ga, Se, or CuInGa (CIG) powder 403 by conduction causing them to vaporize. Once metallic and Se vapors arrive at the 405 substrate structure comprised of 102/101/100, they start to react and form thin film CIGS.
12) Still referring to FIG. 4, procedure 12 comprises all of the above, except that the open boats or crucibles 402 are placed on a susceptor 401 that absorbs electromagnetic waves (RF and Microwaves) and converts them into heat. In one embodiment, the heat will thereby transfer to the elements, or the CIG powder 403 by conduction. The open boats' or crucibles' 402 heat causes the elements or CIG and powder 403 and Se to heat up and vaporize. Then CIGS film is formed on the 405 substrate structure, comprised of 102/101/100.

### Method II

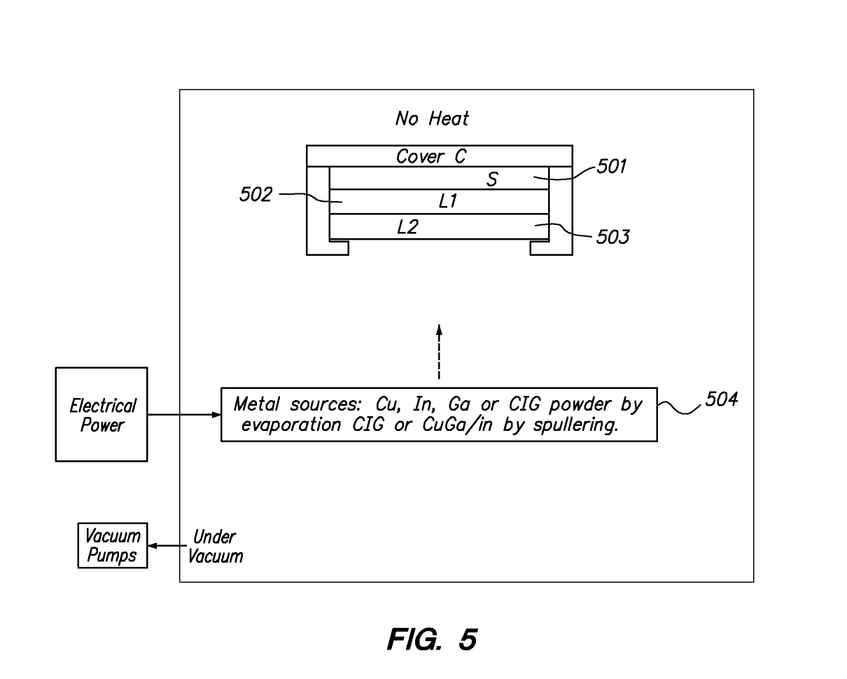

Referring to FIG. 5, Cu, In and Ga 504 are deposited by PVD onto an unheated substrate 501 which is already coated with a barrier layer (L1) 502 and a back contact layer (L2) 503. In one embodiment, Sodium as an important dopant for CIGS recrystallization, is introduced through the Soda-Lime-Glass or from an external source (e.g. NaF) if a different substrate is used. Here, Cu, In and Ga or CIG or CuGa/In, or CuGa/CuIn 504 are deposited by PVD with a Cu/(In+Ga) ratio of 0.80-0.90 and Ga/(In+Ga) of 0-1. Thereafter, the (Cu, In, Ga)/102/101/100 structure is then taken out to be selenized.

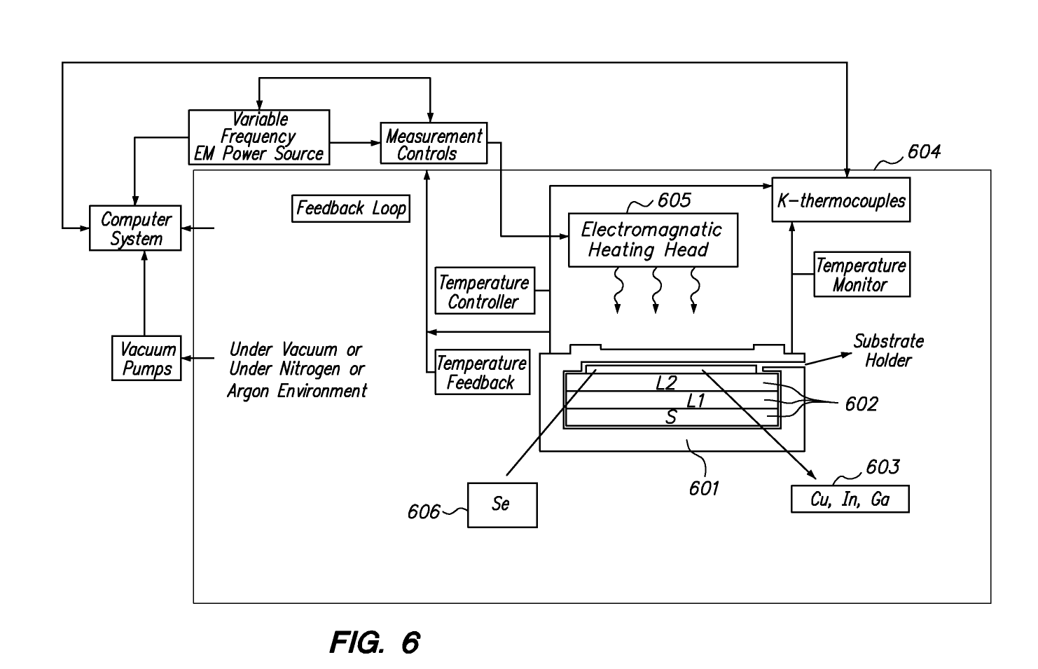

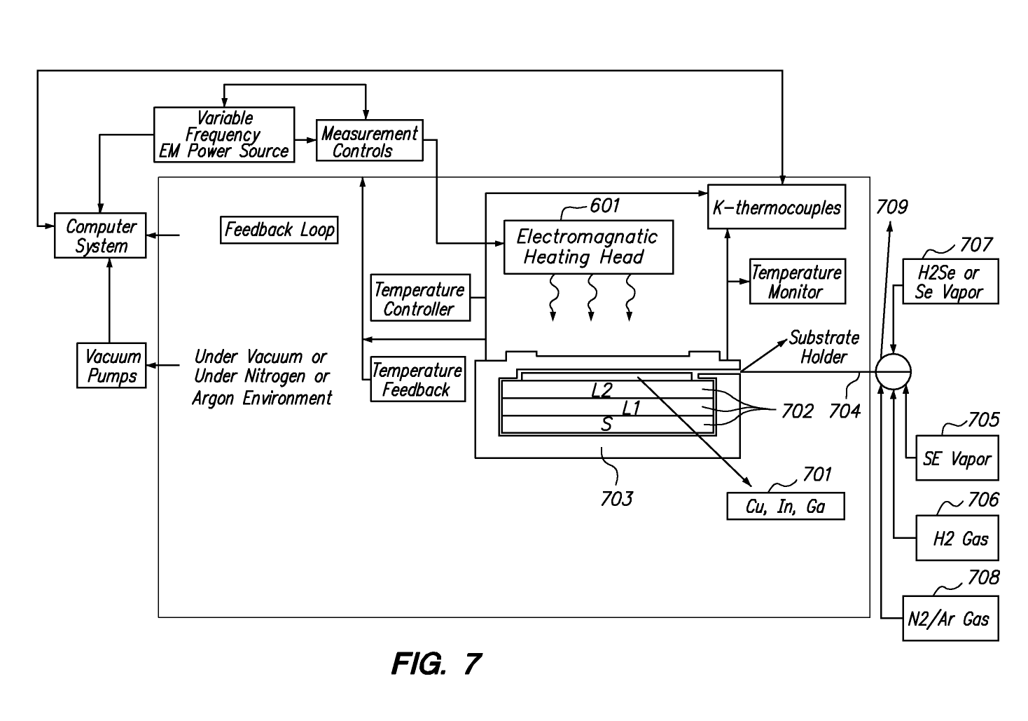

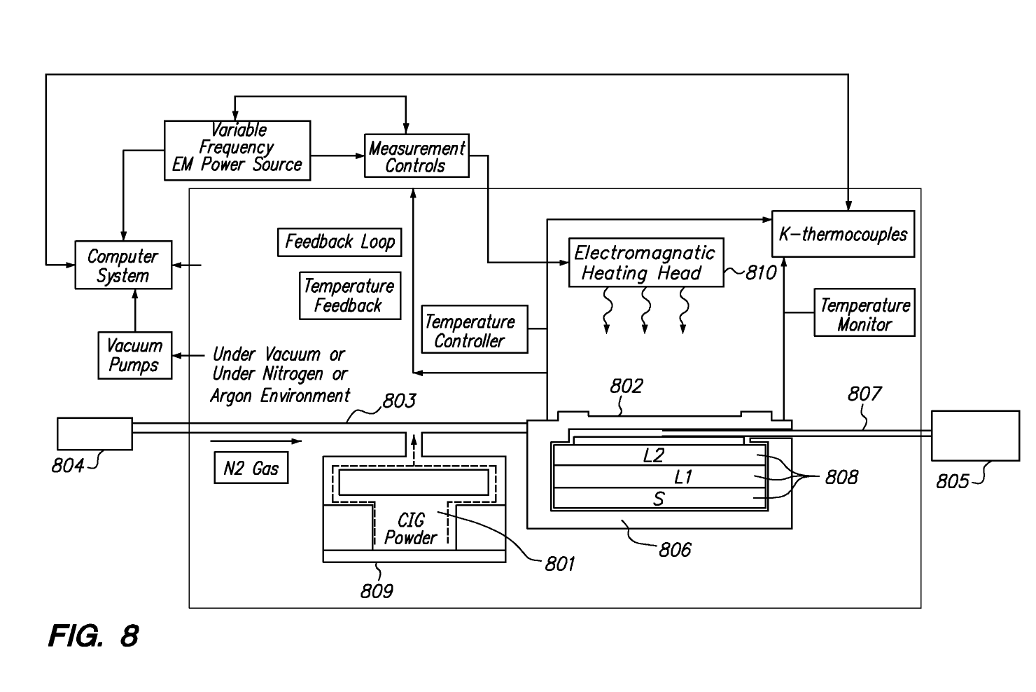

Next, three different approaches to selenize the Cu,In,Ga structure is disclosed in FIGS. 6, 7 and 8. Specifically, FIG. 6 discloses the first approach of selenization of Se on top of the metals. In FIG. 7, a second approach is disclosed using in-situ selenization with Se or H2Se under vacuum or in an inert gas environment (Nitrogen or Argon). FIG. 8 discloses a third approach wherein the use of H2 gas, Se vapor, N2 or Ar gas is embodied.

### First Approach:

Referring to FIG. 6, in one embodiment, the (Cu,In,Ga) 603/102/101/100 structure 602 is placed inside a box 601 which can be placed inside a furnace 604 that is heated to the CIGS crystallization temperature of (400-800° C.) with an electromagnetic heating source 605. The structure is then heated up to >400° C. in the presence of Se 606 in an inert gas ambient (e.g. Nitrogen or Argon) at atmospheric pressure or under high vacuum (pressure less than 1×10⁻⁶ Torr). The selenization and heating steps are necessary to activate the formation of Cu-poor CIGS chalcopyrite structure. In this approach, the substrate is heated using EMH (RF and Microwaves). Box 601 is made from a material that belongs to a class of materials which possess the capability of absorbing EM waves (RF and Microwaves) and converting them into heat (e.g. SiC). As box 601 heats up, the ((Cu, In, Ga)/Se) structure heats up by conduction and EM heating. Any of the temperature profiles described above can be used to deposit CIGS films. Different deposition times can be used as well.

### Second Approach:

The second approach to selenize the (Cu,In,Ga) structure is to use in-situ selenization using Se and/or H2Se. Referring to FIG. 7, in this approach the (Cu,In,Ga) 701/L2/L1/S structure 702 can be placed inside a box 703 made from a class of materials that absorb EM waves (RF and Microwaves) (example: SiC). In one embodiment, the box 703 is heated using EMH to a temperature in the range of 400-800° C. Se vapor 705 or H2Se gas 706 can then be delivered to the box 703 using a quartz tubing 704 or tubing made from another material (e.g. SiC or graphite, or ceramic). This will allow the formation of thin film CIGS. In one embodiment the tubing is controlled by a 4 way valve 709 which feeds H2Se Vapor 707, or Se Vapor 705, H2 gas 706, or N2/Ar gases 708.

### Third Approach:

Continue to refer to FIG. 7, in this approach, the selenization process can be completed by delivering H2 706 and Se vapor 705 to the box 703 with or without N2/Ar 708. Specifically, N2/Ar gas 708 can be introduced as the selenization methods of the second approach discussed in the preceding paragraph via the 4-way valve 709. In one embodiment, the N2/Ar gas 708 is introduced into the chamber from second tubing.

It is known that the skin depth of a high conducting metals is about 0.6-6 μm, and as high as 50 μm for metals in general. Total CIGS film thickness needed is less than less than 5 μm typically ˜2.5 μm). Thus, the dissipated EM waves (RF and Microwaves) in a CIGS film are capable of generating heat. Based on this, Cu, In and Ga can be heated using EMH (RF and Microwaves), and the box 703 can be made from a material that is transparent to EM waves (RF and Microwaves). The EM waves (RF and Microwaves) waves will then heat Cu, In, and Ga 701 and therefore activate the formation of CIGS.

Additionally, EM waves ranging from 3 kHz to 300 GHz can be used to heat the target by selecting a certain frequency and applying it to the heating head used to heat the target. The selected frequency should be appropriate for the material(s) to be heated. The target here maybe a good conductor (e.g. metals like Cu, In and Ga and all their possible metallic alloys) or a poor conductor (like glass), or a semiconductor (e.g. SiC) or other materials (e.g. SiN, MoSe2 or CuI(In,Ga)3Se5). This allows for selective heating. For example, heating a certain layer in the [(Cu, In, Ga, Se)/(Back contact)/(Barrier Layer)/Substrate] structure directly by EMH can be achieved by placing the structure in box 703 which in this case can be made from a material that is transparent to EM waves (RF and Microwaves) (e.g. made from Alumina-Al2O3) so that electromagnetic (EM) RF and Microwaves pass through the EM transparent structure 703 and heat the target layer(s) in the [(Cu, In, Ga, Se)/(Back contact)/(Barrier Layer)/Substrate] structure.

Furthermore, an inductive coil can be used as heating head to heat Cu, In, Ga or Se or any of their alloys (e.g. partially reacted CIGS, very Cu-poor CIGS, etc.). The same heating head can be used to heat Se as well. In one embodiment, the target material to be heated should be placed in a position where the magnetic field is maximized, and the container box 703 is transparent to EM waves (RF and Microwaves). Furthermore, two capacitive electrodes can be used as the heating head to heat glass (whether rigid or flexible), SiN, SiC, NaF, etc. In one embodiment, the target material to be heated should be placed in such away where the electric field is maximized.

### Method III

In yet another aspect of the invention, another method of a deposition process and an apparatus to fabricate CIGS thin films is disclosed. Referencing to FIG. 8, this method combines the delivery of the different elements, the selenization and the heating into one system as shown in FIG. 8. Specifically, CIG powder 801 with 0.80-0.90 Cu/(In+Ga) ratio is used as the source for the metals and H2Se gas and/or Se vapor 805 is used for selenization. More specifically, CIG powder 801 is heated and converted to vapor. It is then delivered to the heating area 802 by tubing set A 803 which also capable of carrying N2 gas 804 to the heating area 802. The box 806 is then heated using EMH (RF and Microwave heating) to a temperature in the range of 400-800° C. for CIG deposition. Thereafter, H2Se and/or Se gas 805 are delivered to the heating area 802 via tubing set B 807 to selenize the Cu, In, Ga precursor 808.

### Additional Embodiments

In one embodiment of the invention, selective Heating CIGS formation can be achieved using the 3-D volumetric EM heating described above in Method II as follows:
a. Heat Cu, In, Ga, and Se using EMH to a temperature from 400-800° C., and, as a result, form CIGS.
b. To overcome the Ga segregation problem in the back, select a frequency that's capable of heating Ga first and therefore Ga will selenize first allowing it to distribute uniformly.
c. To alter the reaction pathway in a favorable way, select a frequency to heat Cu first, which allows the formation of CuSe and therefore results in the formation of high quality CIGS grains and high efficiency solar cells.
d. Design the heating system in such away to result in the formation of CIGS with large grains and high device conversion efficiency.
e. Alternatively to a-d, we can heat the glass substrate using EMH. The glass will heat up causing the barrier and the back contact layers (L1/L2) to be heated. The heat transfers to the Cu, In, Ga and Se elements and their alloys to activate the formation of CIGS.
f. In addition, SiC as a well known microwave absorber material can be used as a barrier layer and susceptor. SiC (or SiCN) can be deposited on a glass substrate to prevent and/or minimize impurities and Sodium (Na) diffusion from the glass. Chemical Vapor Deposition (CVD) or Physical Vapor Deposition (PVD) techniques can be used to deposit SiC. On top of the SiC, a 1.2 μm Mo layer can be deposited by DC magnetron sputtering, followed by the deposition of Cu, In, Ga, and Se by PVD or any other technique. Then the whole structure is exposed to EMH (RF and Microwaves) using aforesaid Method II. Glass and SiC will be heated first, then the heat transfers to all layers above it including Mo, Cu, In, Ga, Se, and NaF. When the temperature reaches above 400° C., the constituents will react to form Cu-poor chalcopyrite CIGS from which CIGS thin film solar cells can be fabricated (given 0.80<Cu(In+Ga)<0.90). The thickness of the CIGS layer is less than 5 μm (typically 1.5-2.5 μm).

In another embodiment of the invention, FFEM and VFEM 3-D or volumetric heating of room-temperature Cu, In, Ga, Se and NaF on Mo coated substrates (glass, metallic sheets or polyimide) results in more depth compositional uniformity of Cu, In, Ga and Se; in particular for Ga; compared with traditional heating methods.

In yet one other embodiment, VFEM (3-D) or volumetric heating results in more uniform compositional distribution (whether lateral or along the depth of the film) of all elements compared with films heated by FFEMH. Ga is more uniform and less segregated for samples heated by VFEMH. VFEMH will result in better compositional uniformity of Cu, In, Ga and Se.

In yet another embodiment of the invention, since Se has a dielectric constant of 6.1-11, it will be heated first where Cu, In and Ga are deposited as shown in FIG. 5, then a layer of Se (1.4 μm) with a layer of NaF already included are evaporated, and next EMH is applied as shown in FIG. 6. The heat will transfer by conduction to the other constituents (Cu, In, Ga, and NaF), and allow selenization of the metals and forming CIGS. CIGS which is not as conductive as the metal constituents and has certain dielectric constant which makes it possible for CIGS (partially-reacted) to be heated by VFEMH heating until all metals and Se are fully reacted and converted into the Cu-poor chalcopyrite CIGS thin film. In the beginning of the heating process, the Se volume will be heated first. As the heating progresses, CIGS volume will be heated since the RF and Microwave heating is 3-D.

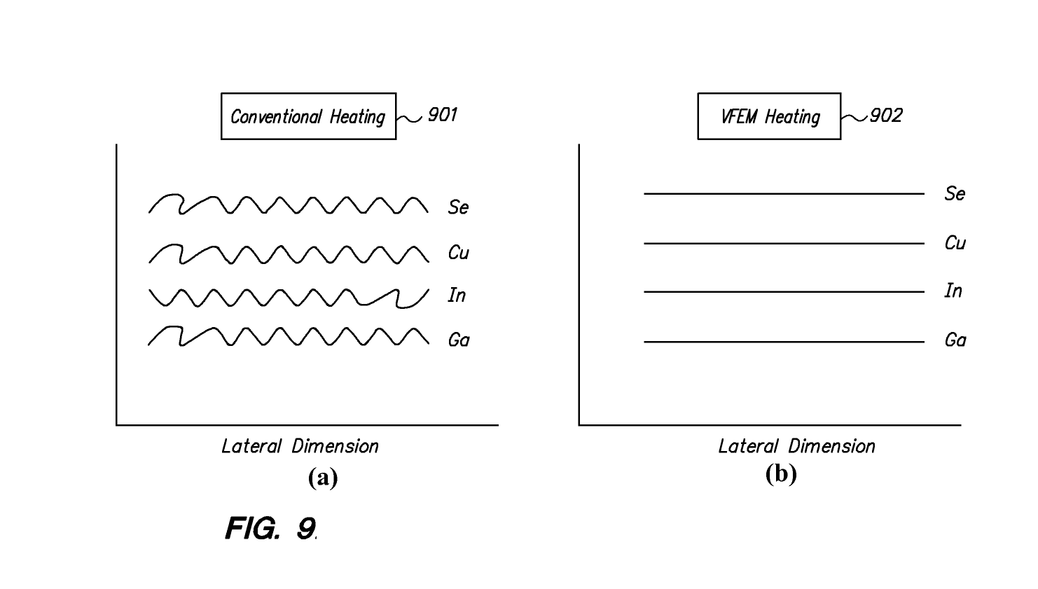

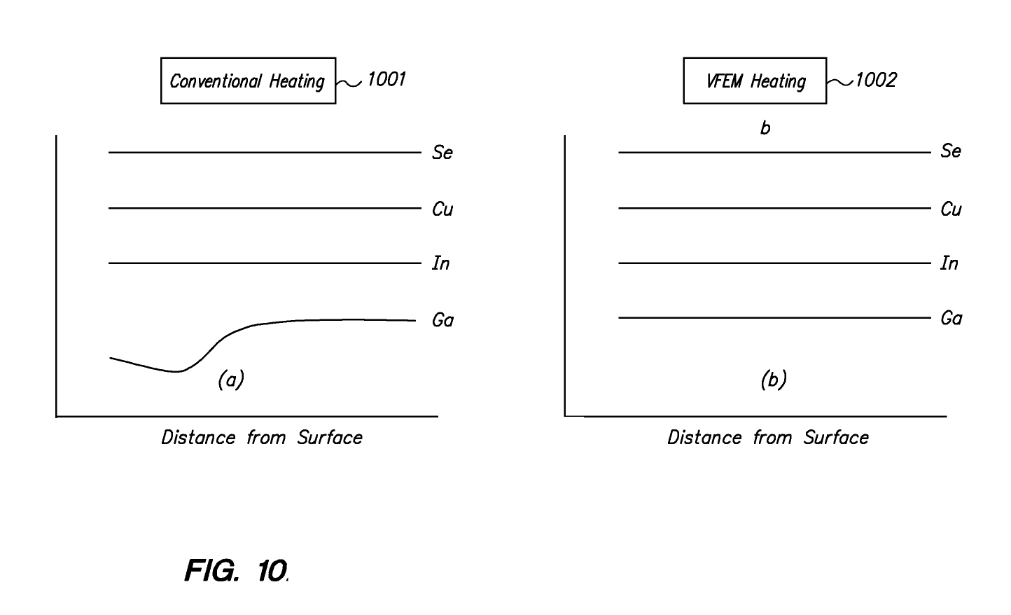

In yet another embodiment of the invention the VFEMH process by which the electromagnetic waves (RF and Microwaves) transfer to the Se and CIGS volumes in three dimensions and cause the molecules to oscillate and produce heat, this heating process will result in a uniform Ga composition profile in the lateral direction and Ga will not be segregated in the back of film as is the case in conventional heating. FIGS. 9 and 10 show that CIGS films heated with RF and Microwave heating are more uniform laterally and in the depth direction, respectively, compared with CIGS films heated with conventional heating methods.

In one other embodiment, Copper, Indium and Gallium are metals but Selenium is a semi-metal. These four elements are reacted at a temperature of 400-800° C. to form the Cu-poor CIGS phase which is a semiconductor. Depending on the reaction pathway, different intermediate phases may form. These intermediate phases range from metallic, such as CuInGa, to semiconducting, CuInGaSe2. Other phases are likely to form, such as CuI(In, Ga)3Se5 which has a band-gap of 1.4 eV. The starting mix of the materials is metallic Cu, In and Ga, along with non-metallic Se. The final outcome after reaction is the semiconducting CIGS. During the transition from metallic/nonmetallic to the semiconducting, a number of phases may form (metallic and/or semiconducting). In addition, Mo is the metallic back contact electrode. During Selenization, MoSe2 may form and this phase has a bandgap of ˜1.4 eV. So, MoSe2 may also be heated by EMH. The whole structure is grown on a barrier coated glass, such as Soda Lime glass. A barrier layer to prevent diffusion of impurities from the glass substrate is also deposited. This barrier layer maybe SiN, SiC, etc. These layers can also be heated using RF and Microwave heating (EMH).

Referring to FIG. 9, the diagram shows that VFEMH results in more lateral compositional uniformity 902 compared with conventional heating diagram 901. Likewise, FIG. 10 shows that VFEMH results in more depth compositional uniformity 1002 compared with conventional heating diagram 1001.

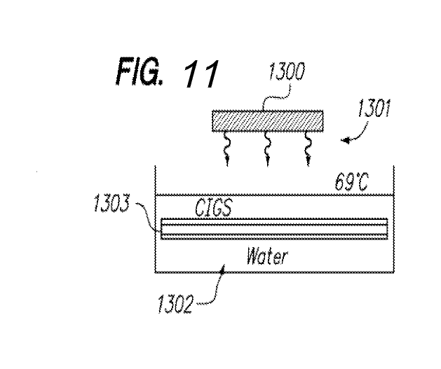

Referring to FIG. 11, in one embodiment, the CdS or ZnS or any buffer layer (e.g. In(Ga)2Se3, In(Ga)2S3, ZnO, etc.) that is adequate to be used as the n-side of the junction in a CIGS solar can be made by heating their respective CBD solutions using RF/Microwave heating (EMH) method as disclosed by Abushama in provisional patent disclosure no 617739984. This method of heating the solutions using RF/Microwaves comprises using a RF/Microwave heating head 1300 generating heating waves 1301, which are directed to the water-based solution 1302 underneath. The water (H2O)-based solution 1302 has a number of dissolved chemicals. In reference to FIG. 1, the buffer layer 104 is the n-side of the p-n junction and is deposited on top of the CIGS layer 103, which is deposited on the 102/101/100 substrate structure. The whole structure 103/102/101/100 is then immersed in the water (H2O) based solution 1302. The water-based solution has a number of chemicals dissolved in it. For example, in the case of Cadmium Sulfide (CdS) buffer layer 104, the water-based solution 1302 includes Cadmium Sulfate (CdSO4), Thiourea (NH2CSNH2), and Ammonium Hydroxide (NH4OH). This water based solution 1302 is heated as the solution and/or the vessel containing the solution absorbs the RF/Microwave waves 1301. Submerged in the heated solution, a buffer layer 1303 or 104 is deposited (e.g. CdS or ZnS) using Chemical Bath Deposition (CBD).

1. A method of depositing CIGS thin film for solar panel construction comprising:
a. providing a chamber;
b. providing a substrate and placing said substrate inside said chamber;
c. providing a material source;
d. placing metals or semi-metals in said material source inside said chamber;
e. reducing pressure within said chamber;
f. heating said substrate with an electromagnetic heating source;
g. Heating material source with an electromagnetic heating source,
h. performing deposition of said metals and/or semi-metals to said substrate.

2. The method of claim 1 wherein said pressure within the chamber is less than 1×10⁻⁶ Torr.

3. The method of claim 1 wherein said electromagnetic heating source is radio frequency heating.

4. The method of claim 1 wherein said electromagnetic heating source is microwave heating.

5. The method of claim 1 further comprising placing said substrate with one side residing on first susceptor.

6. The method of claim 5 wherein said first susceptor is made with material capable of absorbing electromagnetic waves (RF and Microwaves) from said electromagnetic heating source.

7. The method of claim 5 wherein said first susceptor is made with material transparent to electromagnetic wave from said electromagnetic heating source.

8. The method of claim 5 wherein said first susceptor is coated with material capable of absorbing electromagnetic waves (RF and Microwaves) from said electromagnetic heating source.

9. The method of claim 1 further comprising placing said metals or said semi-metals in an open boat or crucible.

10. The method of claim 9 further comprising placing said open boat or crucible on a second susceptor wherein a second electromagnetic heating source is further used for heating the second susceptor.

11. The method of claim 10 wherein said second susceptor is made with material capable of absorbing electromagnetic waves (RF and Microwaves) from said second electromagnetic heating source.

12. The method of claim 5 wherein said first susceptor is coated with material capable of absorbing electromagnetic waves (RF and Microwaves) from said electromagnetic heating source.

13. The method of claim 9 wherein said open boat or crucible is coated with material capable of absorbing electromagnetic waves (RF and Microwaves) from said second electromagnetic heating source.

14. The method of claim 13 wherein said open boat or crucible is heated with said second electromagnetic heating source using RF and Microwaves.

15. The method of claim 1 wherein said substrate is comprised of multiple layers.

16. The method of claim 15 wherein at least one of said multiple layers is made with material capable of absorbing electromagnetic waves (RF and Microwaves) from said electromagnetic heating source.

17. The method of claim 15 wherein said multiple layers includes a barrier layer and a back contact layer.

18. The method of claim 1 wherein said substrate is positioned to said material source at a distance of from 1 mm to 30 cm.

19. The method of claim 1 wherein said substrate is positioned to said electromagnetic heating source at an optimal distance.

20. The method of claim 1 wherein said material source is comprised of elements and/or compounds selected from the group consisting of Cu, In, Ga, Se, CuIn, CuGa and CuInGa, to achieve Cu-poor CIGS composition.

21. The method of claim 1 wherein said Cu, In, Ga, Se, CuIn, CuGa, and CuInGa are deposited to said substrate simultaneously to achieve Cu-poor CIGS composition.

22. The method of claim 1 wherein said Cu, In, Ga, Se, CuIn, CuGa, and CuInGa are deposited to said substrate separately to achieve Cu-poor CIGS composition.

23. The method of claim 1 wherein said electromagnetic heating source(s) heats said substrate to a temperature range between 300-800° C.

24. A method of deposing CIGS thin film for solar panel construction comprising:
a. providing a chamber;
b. providing a substrate and placing said substrate inside said chamber wherein said substrate is already coated with Cu, In and Ga by physical vapor deposition.
c. providing a material source wherein said material source is Se;
d. placing said material source inside said chamber;
e. reducing pressure within said chamber;
f. heating said substrate with an electromagnetic (RF and Microwaves) heating source;
g. Heating material source with an electromagnetic heating source,
h. performing selenization of said Cu, In, Ga on said substrate.

25. The methods of claims 21 and 22 wherein Sodium is introduced as a dopant for CIGS on said substrate during physical vapor deposition.

26. The method of claim 24 wherein said Se source is in a gaseous state and is introduced to said substrate via tubing and/or a carrier gas.

27. The method of claim 26 wherein said tubing is further comprised of a valve wherein said valve controls the flow of said Se source.

28. The method of claim 26 wherein N2 or Ar gas is further introduced via said tubing as a carrier gas.

29. A method of depositing CIGS thin film for solar panel construction comprising:
a. providing a first chamber;
b. providing a substrate and placing said substrate inside said chamber;
c. providing a second chamber;
d. providing a portion of Cu, In and Ga elements or CuInGa alloy wherein said Cu, In and Ga or said CIG alloy is heated by a first heating source;
e. reducing pressure within said chambers
f. Converting said Cu, In and Ga or CuInGa powder into vapors and transporting said vapors to a heating area by a first tubing wherein said heating area is comprised of a second heating source and said substrate wherein said second heating source is a second electromagnetic heating source;
g. Providing a portion of Se vapor or H2Se gas and introduce said portion of Se vapor or H2Se gas to said heating area via a second tubing;
h. heating said substrate with said second heating source;
i. perform a crystallization of said portion of Se or H2Se and said portion of Cu, In and Ga to said substrate.

30. The method of claim 29 wherein said Cu, In and Ga are in CuInGa alloy powder form before said Cu, In and Ga is heated by said first heating source.

31. The method of claim 29 wherein said first heating source is an electrical heating source.

32. The method of claim 29 wherein said first heating source is a second electromagnetic heating source providing RF and Microwaves.

33. The method of claim 32 wherein said second electromagnetic heating source originates from said first electromagnetic heating source.

34. An apparatus for deposition of a plurality of elements onto a solar cell substrate comprising:
a. a chamber;
b. a substrate;
c. a plurality of elements for deposition onto said substrate;
d. an electrical source to conduct deposition of said plurality of elements to said substrate;
e. a electromagnetic heating source to heat said substrate;
f. a vacuum source to control the pressure environment of said chamber.

35. The apparatus of claim 34 wherein said electromagnetic heating source heats said substrate at a temperature ranging between 300-800° C.

36. The apparatus of claim 34 wherein said substrate is positioned within a susceptor.

37. The apparatus of claim 36 wherein said susceptor is made with material capable of absorbing electromagnetic waves (RF and Microwaves) from said electromagnetic heating source.

38. The apparatus of claim 37 wherein said susceptor is made of SiC, or SiCN.

39. The apparatus of claim 36 wherein said susceptor is made with material transparent to electromagnetic waves (RF and Microwaves) from said electromagnetic heating source.

40. The apparatus of claim 34 wherein said plurality of elements for deposition onto said substrate is placed in an open boat or a crucible.

41. The apparatus of claim 40 wherein a second electromagnetic heating source is provided and wherein said open boat or a crucible is placed on a susceptor wherein said susceptor is heated by said second electromagnetic heating source using RF and Microwaves to a temperature range of in 50-2000° C.

42. The apparatus of claim 40 wherein said susceptor is made of material capable of absorbing electromagnetic waves (RF and Microwaves) from said second electromagnetic heating source.

43. The apparatus of claim 40 wherein said crucible or open boat is coated with material capable of absorbing electromagnetic waves (RF and Microwaves) from said second electromagnetic heating source.

44. The apparatus of claim 34 wherein said plurality of elements for deposition onto said substrate is carried into said chamber via a tubing and a carrier gas.

45. The apparatus of claim 44 wherein the carrier gas can be selected from the group comprised of N2, Ar, Ne and He.

46. An apparatus for deposition of a plurality of elements onto a solar cell substrate comprising:
a. a chamber;
b. a substrate;
c. a plurality of elements and gaseous materials for crystallization onto said substrate;
d. an electromagnetic heating source to heat said substrate and to conduct crystallization of said plurality of elements and gaseous materials to said substrate;
e. an electromagnetic heating source to heat said plurality of elements;
f. a vacuum source to control the pressure environment of said chamber.

47. The apparatus of claim 46 wherein said plurality of elements for crystallization onto said substrate is carried into said chamber via a tubing and a carrier gas.

48. The apparatus of claim 46 wherein said plurality of elements and gaseous materials for crystallization onto said substrate is transported into said chamber via a tubing and a carrier gas.

49. The apparatus of claim 46 wherein said apparatus further comprises a second enclosure inside said chamber wherein said second enclosure is comprised of a heating source to heat said second enclosure wherein a first portion of said plurality of elements is heated to gaseous state and thereby transported by a carrier gas to said substrate for crystallization.

50. The apparatus of claim 46 wherein said plurality of elements is transported to said substrate for crystallization via a first tubing.

51. The apparatus of claim 48 wherein said second portion of said plurality of gaseous materials is transported to said substrate for crystallization via a second tubing and a carrier gas.

52. The apparatus of claim 50 wherein said plurality of elements is comprised of Cu, In, and Ga elements.

53. The apparatus of claim 52 wherein said Cu, In, and Ga elements are in elemental form or in the form of CuInGa powder, or CuGa and CuIn powders or any other powder or solid combination.

54. The apparatus of claim 46 wherein heating source is a second electromagnetic heating source.

55. The apparatus of claim 48 wherein said tubing is coupled with a valve to control the transportation of said plurality of gaseous materials.

56. The apparatus of claim 51 wherein the carrier gas can be selected from the group comprised of N2, He, Ne and Ar

57. The method of claim 1 wherein said electromagnetic heating source is fixed frequency electromagnetic heating or variable frequency electromagnetic heating.

58. The method of claim 24 wherein said electromagnetic heating source is fixed frequency electromagnetic heating or variable frequency electromagnetic heating.

59. The method of claim 34 wherein said electromagnetic heating source is fixed frequency electromagnetic heating or variable frequency electromagnetic heating.

60. The apparatus of claim 46 wherein said electromagnetic heating source is fixed frequency electromagnetic heating.

61. The apparatus of claim 46 wherein said electromagnetic heating source is variable frequency electromagnetic heating.

62. The apparatus of claim 46 where said electromagnetic heating source is capable of heating said plurality of elements and/or compounds to a temperature range from 50-2000° C.

63. The method of 62, wherein said plurality of elements and/or compounds is comprised of Cu, In, Ga, Se, CuIn, CuGa, CuInGa, In(Ga)2Se2, Cu2-xse and/or CuInGaSe2.

64. A method of depositing CIGS thin film for solar panel construction comprising:
a. providing a vessel wherein said vessel further comprises a Water-based Chemical Bath solution wherein said water-solution further comprises one or more target compounds;
b. providing a CIGS-coated substrate and placing said CIGS—coated substrate inside said vessel;
c. providing an electromagnetic heating source;
d. heating said vessel and said water-based Chemical Bath solution with said electromagnetic heating source;
e. allowing said target compounds to deposit onto said CIGS coated substrate as said water-based solution is heated.

65. The method of claim 64 wherein said target compound is Cadmium Sulfide (CdS).

66. The method of claim 64 wherein said target compound is Zinc Sulfide (ZnS).

67. The method of claim 64 wherein said target compound is Indium Selenide (In2Se3)

68. The method of claim 64 wherein said target compound is Indium Sulfide (In2S3).

69. The method of claim 64 wherein said target compound is Zinc Oxide (ZnO).
